(19) United States
(12) Patent Application Publication
(10) Pub. No.: US 2015/0016080 A1
(43) Pub. Date: Jan. 15, 2015

(54) METHOD FOR MANUFACTURING AN EMBEDDED PACKAGE AND STRUCTURE THEREOF

(71) Applicant: APTOS TECHNOLOGY INC., Hsinchu County (TW)

(72) Inventors: Chen Hsuan Lung, Hsinchu County (TW); Chien Hsien Lu, Hsinchu County (TW); Ya Yun Cheng, Hsinchu County (TW); Kuo Hua Lin, Hsinchu County (TW)

(21) Appl. No.: 14/328,598

(22) Filed: Jul. 10, 2014

(30) Foreign Application Priority Data
Jul. 11, 2013 (TW) 102124848
Sep. 12, 2013 (TW) 102133054

(51) Int. Cl. H05K 1/18; H05K 3/30; H05K 1/11

(52) U.S. Cl. CPC H05K 1/188; H05K 1/111; H05K 3/303
USPC 361/767; 29/832; 29/841

(57) ABSTRACT

A method for manufacturing an embedded package comprises the steps of: coupling at least one first embedded body including at least one connection port with a first circuit substrate and packaging the first embedded body and the first circuit substrate to form a package; and exposing the connection port of the package on an outer side of the package for other electronic carriers to couple with. The invention can overcome the disadvantage of the conventional System in Package manufacturing process which integrally packages multiple ICs in a same package to result in discard of the entire package because of failure of a single IC. The method of the invention makes assembly simpler, expansion, test and replacement of IC components easier, and also can reduce manufacturing time and accumulated heat, lower the cost and improve yield rate.

### FIELD OF THE INVENTION

The present invention relates to a method for manufacturing a package and structure thereof, particularly an integrated package comprising an embedded body and the structure thereof.

### BACKGROUND OF THE INVENTION

In recent years semiconductor package technology includes two-dimensional System on Chip (SoC) which aims to cluster electronic systems into integrated circuits formed on a single chip. It has many advantages such as lower power consumption, higher performance and smaller package area. But design of SoC takes a great deal of time, and packaging different elements on one IC still takes significant area on the produced IC, hence its range of application is limited.

System in Package (SiP) is a newly developed package technique which deploys all or most electronic functions of a system or sub-system in an integrated substrate. Compared with SoC it has many benefits such as smaller size, higher performance, shorter development cycle and lower cost. System in Package (SiP) includes many types of techniques, for example, three dimensional integration system-in-package, 3D IC and through silicon via (TSV).

However, through silicon via (TSV) technique has a much higher technical threshold and manufacturing cost, thus it is not widely adopted yet. At present other techniques such as Multi-chip Package (MCP), Stack Die, Package on Package (PoP), Package in Package (PiP) and Embedded Substrate are the main stream in the package industry.

The manufacturing methods of SiP adopted the technique of MCP and the like generally integrate a plurality of ICs into a package. However, the ICs before integration are usually not all known good dies. Hence before and after integration of ICs the problems of complex tests and heat dissipation are encountered. Moreover, in the event that any IC is damaged, the entire 3D IC has to be discarded.

Hence how to provide a solution to improve the SiP technology is a critical issue yet to be resolved.

### SUMMARY OF THE INVENTION

The primary object of the present invention is to provide a package manufacturing method to facilitate assembly, expansion, test and replacement.

To achieve the foregoing object, the present invention provides a method for manufacturing an embedded package that comprises the steps of: coupling at least one first embedded body which includes at least one connection port with a first circuit substrate and packaging the first embedded body and the first circuit substrate to form a package; and cutting the package to expose the connection port of the first embedded body at an outer side of the package.

The invention also provides an embedded package structure which includes at least one package includes a first circuit substrate and at least one first embedded body to couple with the first circuit substrate. The first embedded body includes at least one connection port open at an outside of the package.

By means of the techniques set forth above, the invention improves the shortcoming of conventional techniques that packages the entire IC in one package to result in discard of the entire IC chip when a single IC is failure. Moreover, the package can be made with high pin count to serve as a carrier and the peripheral IC can be inserted into the connection port, thus the peripheral IC, module and controller can be inserted and coupled according to different requirements, or other systems or equipments also can be connected with the package through flat cables.

In short, the method for manufacturing an embedded package and structure thereof according to the invention provides many advantages, notably:

1. Easier in assembly, expansion, test and replacement of IC components;

2. Shorter manufacturing time;

3. Reduce heat accumulation;

4. Reduce cost; and

5. Improve production yield.

The foregoing features and advantages of the invention will be more readily apparent from the following detailed description, which proceeds with reference to the accompanying drawings.

### BRIEF DESCRIPTION OF THE DRAWINGS

FIG. 1A is a first schematic view for assembling a first embodiment of the manufacturing method of the invention.

FIG. 1B is a second schematic view for assembling the first embodiment of the manufacturing method of the invention.

FIG. 2 is a first schematic view for assembling the first embodiment of the invention with another type of embedded body.

FIG. 3 is a second schematic view for assembling the first embodiment of the invention with yet another type of embedded body.

FIG. 4 is a third schematic view for assembling the first embodiment of the manufacturing method of the invention.

FIG. 5 is a first schematic view for assembling the first embodiment of the invention with another type of package.

FIG. 6 is a second schematic view of the first embodiment of the invention with yet another type of package.

FIG. 7 is a first schematic view of a second embodiment of the manufacturing method of the invention.

FIG. 8 is a second schematic view of the second embodiment of the manufacturing method of the invention showing the assembly process.

FIG. 9 is a third schematic view of the second embodiment of the manufacturing method of the invention after assembly.

FIG. 10 is a schematic view of a third embodiment of the manufacturing method of the invention.

FIG. 11 is a schematic view of the third embodiment of the manufacturing method of the invention in an expanding condition.

FIG. 12 is a schematic view of the structure of the invention.

FIG. 13 is a first schematic view of the manufacturing method of the invention in a cutting process.

FIG. 14 is a second schematic view of the manufacturing method of the invention in the cutting process.

### DETAILED DESCRIPTION OF THE PREFERRED EMBODIMENTS

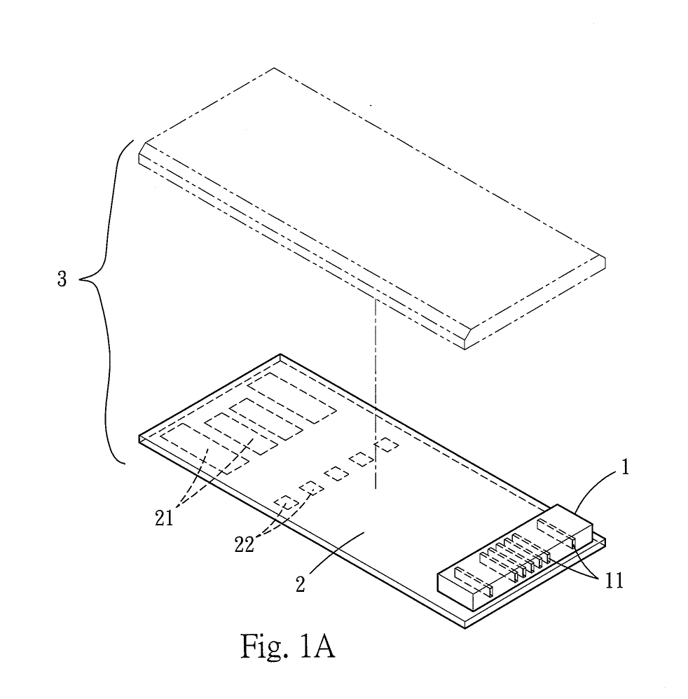

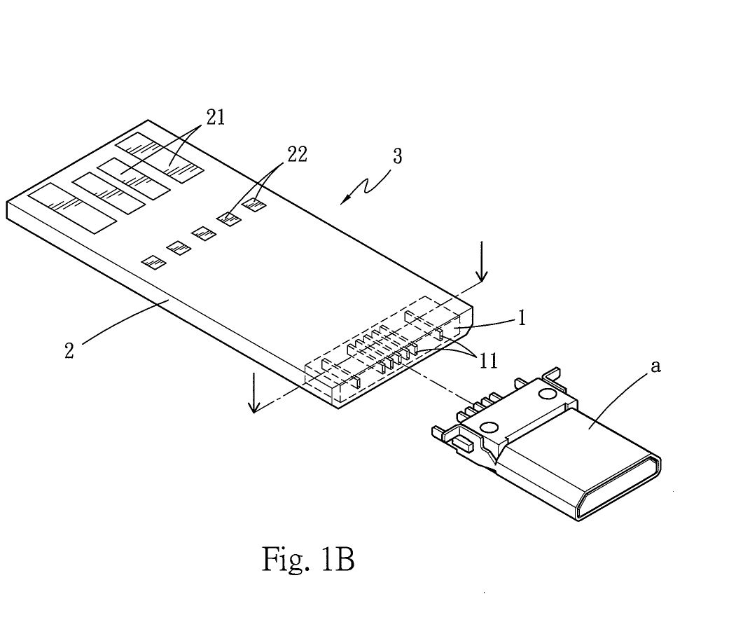

Please refer to FIGS. 1A through 6 for a first embodiment of the method for manufacturing an embedded package according to the invention. To facilitate discussion, a manufacturing process of a USB 3.0/Micro-USB dual connector flash drive is used as an example below. The manufacturing process comprises:

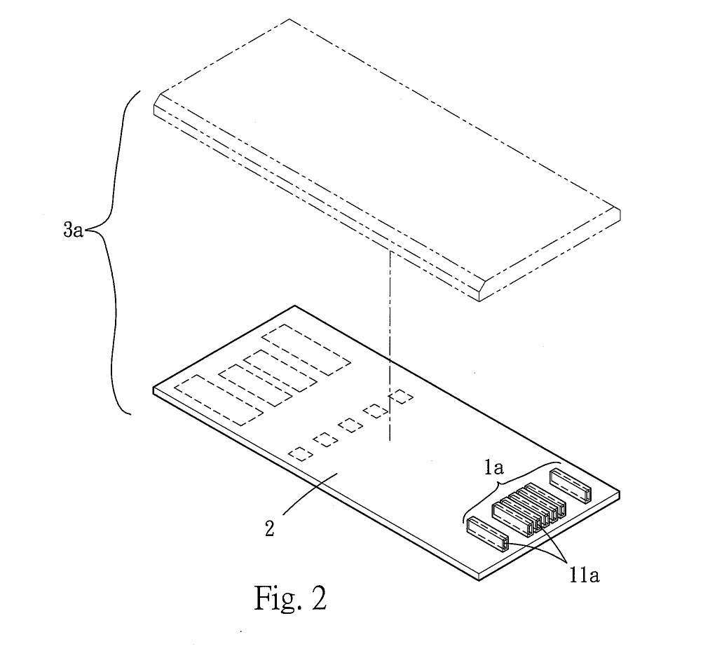

Step 1: Referring to FIG. 1A, coupling an first embedded body 1 including a plurality of connection ports 11 with a first circuit substrate 2 which has flash memory chips (not shown in the drawings), a control circuit (also not shown in the drawings) and metal contacts 21 and 22 for USB 2.0 and USB 3.0. The first embedded body 1 can be male or female formed by an epoxy molding compound (EMC) or through injection molding. A female seat is employed as an embodiment for discussion below. After the first embedded body 1 (or the first embedded body 1a shown in FIG. 2) is coupled with the first circuit substrate 2, they are packaged into a package 3, and the connection ports 11 are not yet exposed at an outer side of the package 3.

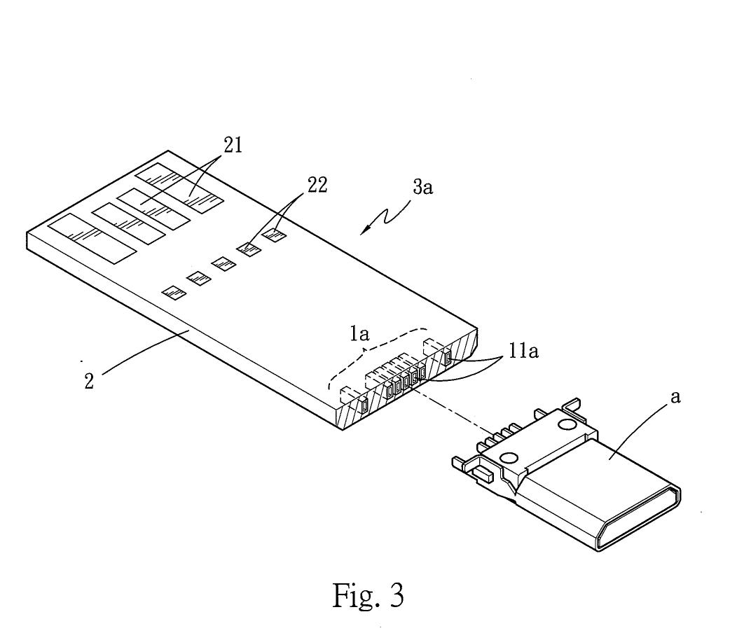

Step 2: Cutting one side (indicated by arrows) of the package 3 where the first embedded body 1 is located to expose the connection ports 11 as shown in FIG. 1B, so that the connection ports 11 are exposed at the outer side the package 3. The first embedded body 1 can be implemented in another type as shown in FIG. 2 which differs from FIG. 1A by having a plurality of first embedded bodies 1a each includes a connection port 11a to couple with the first circuit substrate 2, then are packaged to form the package 3a as shown in FIG. 3. The package 3a also is cut to expose the individual connection ports 11a of the first embedded body 1a at the outer side of the packaged element 3a.

It should be noted that at step 2, the connection ports 11 and 11a can also be exposed and open at the outer side of the package 3 through positioning of the first embedded body 1 (or the first embedded body 1a) at selected positions to save the cutting process.

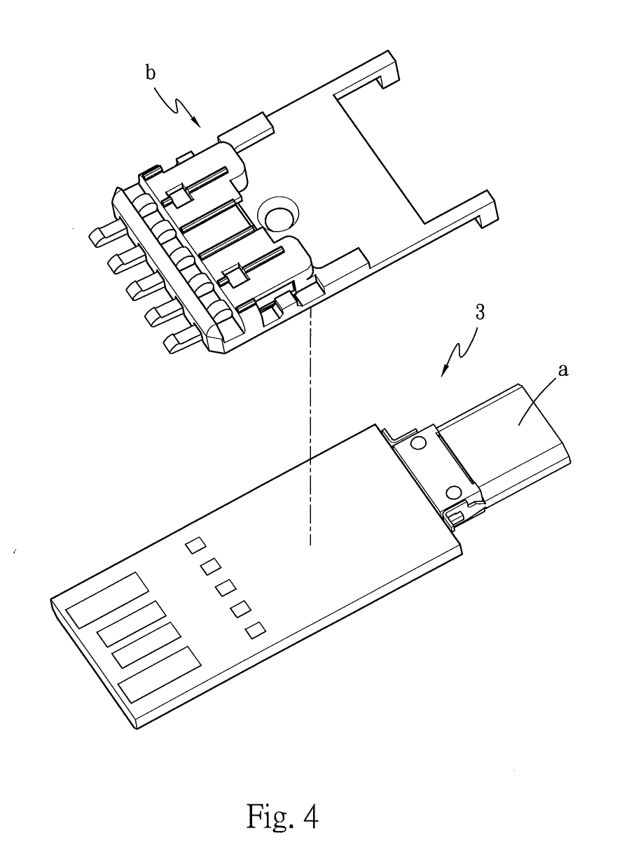

Thus, please refer to FIG. 1B or 3, a micro-USB connector a can be easily inserted and connected with the connection ports 11 or 11a; then as shown in FIG. 4, through a SMT (Surface Mount Technology) or other coupling techniques such as latching or bonding (also can be selectively injecting adhesive) a USB 3.0 connection member b can be coupled with the package 3 (such a coupling technique has been disclosed in R.O.C. patent M439795 which mainly provides a feature to upgrade a memory drive of USB 2.0 interface to support a memory drive of USB 3.0 interface), thereby form an embedded package structure of a USB 3.0/Micro-USB dual connector flash memory drive through the method for manufacturing an embedded package of the invention.

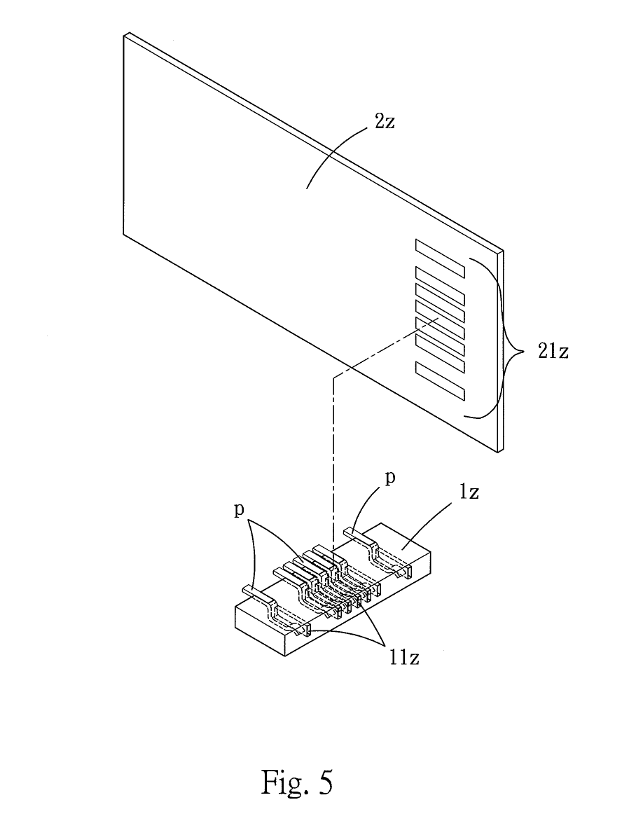

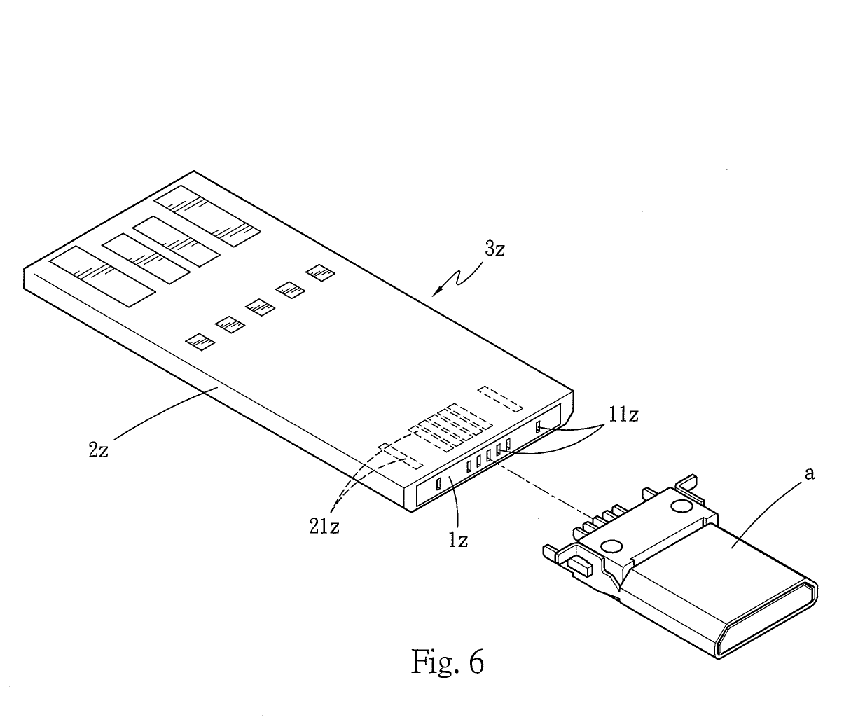

The package 3 at step 1 as previously discussed can further be implemented in another embodiment that a package 3z including a plurality of terminals p, as shown in FIGS. 5 and 6. Prior to step 1, the plurality of terminals p can be positioned in the connection ports 11z and coupled with the first embedded body 1z through injection encasing molding, latching or surface mount technology. The surface mount technology (SMT) discussed here is glue filling. After the coupling is formed, the terminals p have one end extended and exposed at one side of the first embedded body 1z so that the terminals p can connect to metal contacts 21z and form electric connections with the first circuit substrate 2z. Finally, the package 3z is formed through a packaging process; then the package 3z can continue the step 2 previously discussed and install a Micro-USB connector a for power supply or data transmission, thus finish an embedded package structure.

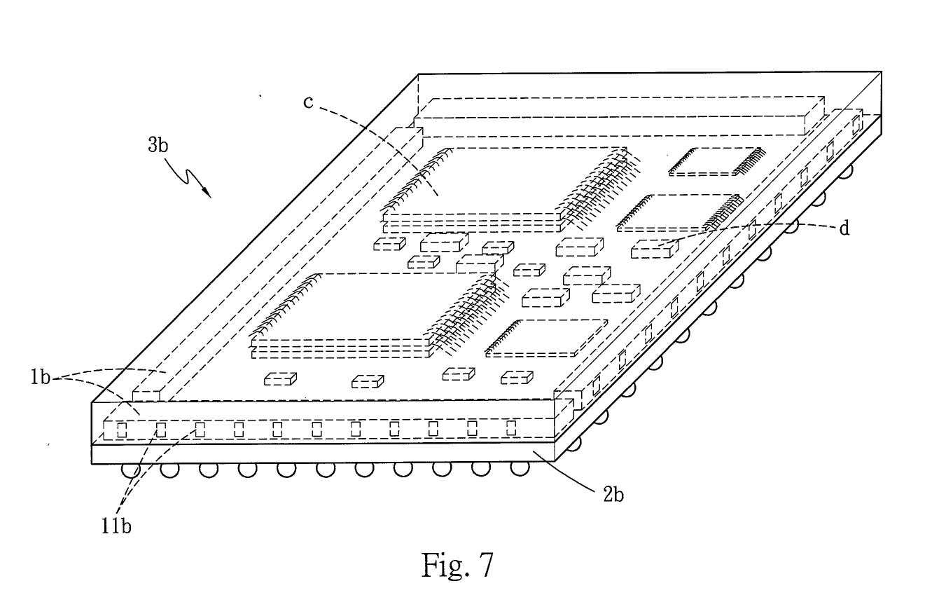

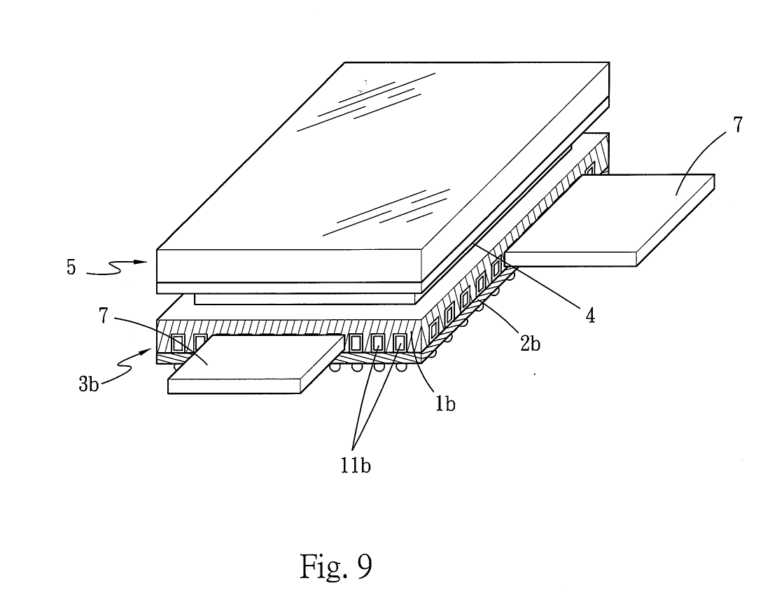

At present the general multi-chip package (MCP) technology integrates and packages two or more memory chips in a same Ball Grid Array (BGA) package through horizontal positioning and/or vertical stacking manner. A second embodiment of the invention also provides a novel application for the MCP technology. Please referring to FIGS. 7 through 9, the method includes:

Step 1: coupling a plurality of first embedded bodies 1b each includes a plurality of connection ports 11b with a first circuit substrate 2b including multiple chips c or electronic elements d, and packaging them to form a package 3b which can be a BGA or Land Grid Array (LGA) with high pin count. In this embodiment a BGA package 3b is used. The first circuit substrate 2b has pins extended to each side thereof so that the first embedded bodies 1b can be positioned at four sides of the first circuit substrate 2b.

Step 2: cutting the four sides of the package 3b to expose the connection ports 11b and make them open at four sides of the package 3b.

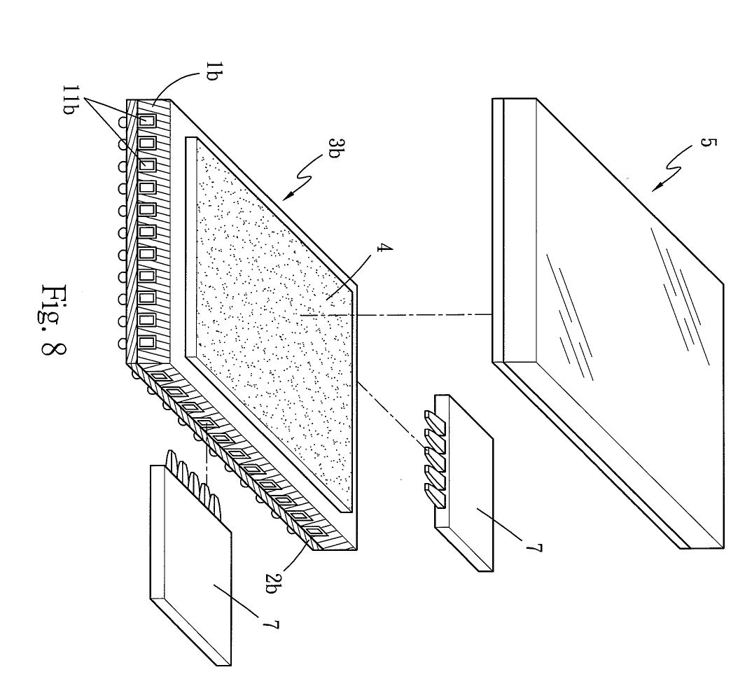

Step 3: stacking a bonding intermediate layer 4 and an first electronic carrier 5 on one side of the package 3b formed at the step 2. The intermediate layer 4 can be thermal grease, a silicon substrate, a washer, a metal layer, a dielectric layer or a thin film. The first electronic carrier 5 can be a circuit substrate, a chip, an electronic element or any package elements. In this embodiment the intermediate layer 4 and the first electronic carrier 5 are respectively thermal grease and a LGA package as shown in FIG. 8. To prevent generation of electromagnetic interference (EMI) after stacking, a sputter process can be executed on the first circuit substrate 2b of the package 3b or the first electronic carrier 5, or a metal material can be interposed between the package 3b and the first electronic carrier 5. Through the steps 1, 2 and 3 previously discussed a package manufacturing method which is simpler, faster and lower cost with improved heat dissipation can be realized.

Furthermore, the package 3b at the step 3 mentioned above can be connected with at least one second electronic carrier 7 with a pin thereon. The second electronic carrier 7 can be another circuit board, a chip, an electronic element, a package element or a line connector for transmission, such as a peripheral IC, a controller, a LGA or BGA package, a flat cable, a signal line, or a transmission line (not shown in the drawings). Therefore the second electronic carrier 7 can be inserted into the connection ports 11b of the package 3b formed at the step 2 to form a SiP product which includes a stacked embedded package inserted by the peripheral IC.

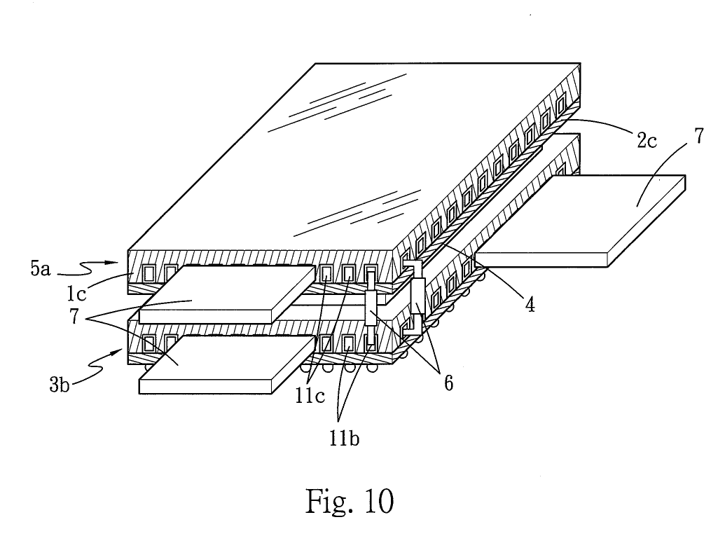

Please refer to FIG. 10 for a third embodiment of the invention. It is different from the second embodiment that the first electronic carrier 5 in the second embodiment is replaced by another LGA-packaged first electronic carrier 5a (i.e. coupling at least one second embedded body 1c with a second circuit substrate 2c, and the second embedded body 1c includes a plurality of connection ports 11c) processed through the steps 1 and 2 as previously discussed. Furthermore, in this embodiment the connection ports 11c of the stacked first electronic carrier 5a can be electrically connected to the connection ports 11b via at least one connecting member 6. The connecting member 6 can be a wire, conductive adhesive or a plated wire formed by a redistribution layer (RDL) technique.

Thus, in this embodiment after stacking of the package 3b and the first electronic carrier 5a, at least one second electronic carrier 7 with the pin thereon or the transmission line (such as flat cable) can be inserted into the connection port 11b of the package 3b (like in the second embodiment). Or, the second electronic carrier 7 with the pin thereon or the transmission line can also be inserted into the connection port 11c of the electronic carrier 5a stacked above the package 3b.

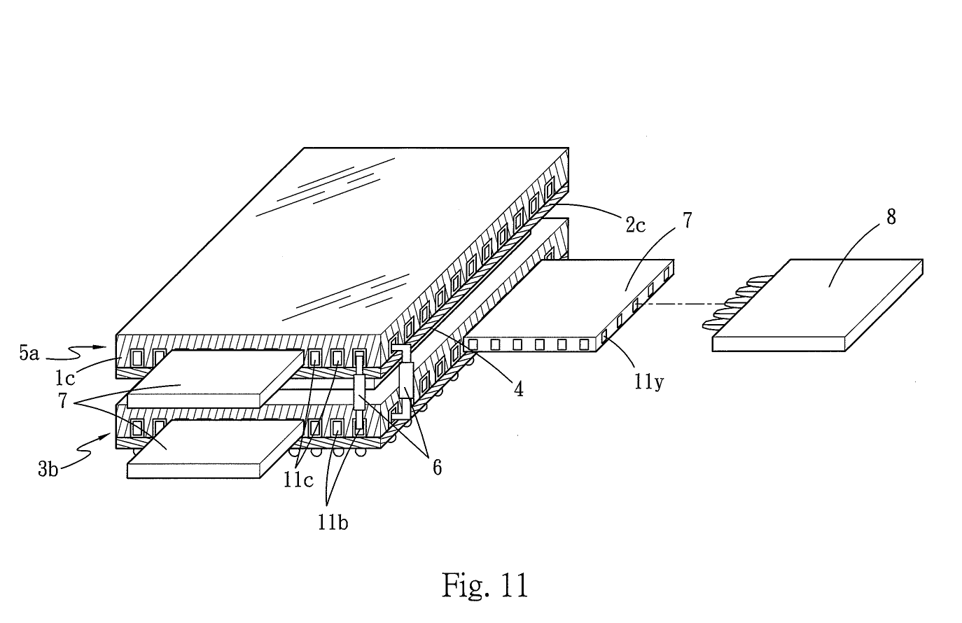

In addition, in the event that the second electronic carrier 7 horizontally inserted into the first electronic carrier 5a also includes the connection ports 11y, the second electronic carrier 7 also can be horizontally inserted by a third electronic carrier 8 with a pin thereon to enhance expandability, as shown in FIG. 11. The third electronic carrier 8 is a circuit board, a chip, an electronic element or a package element. Moreover, each second electronic carrier 7 or the third electronic carrier 8 can also be vertically stacked via the intermediate layer 4. As the manufacturing method of the invention can be flexibly applied in a mixed fashion (i.e. expanded both in horizontal positioning and vertical stacking manner), it gets excellent applicability and expandability.

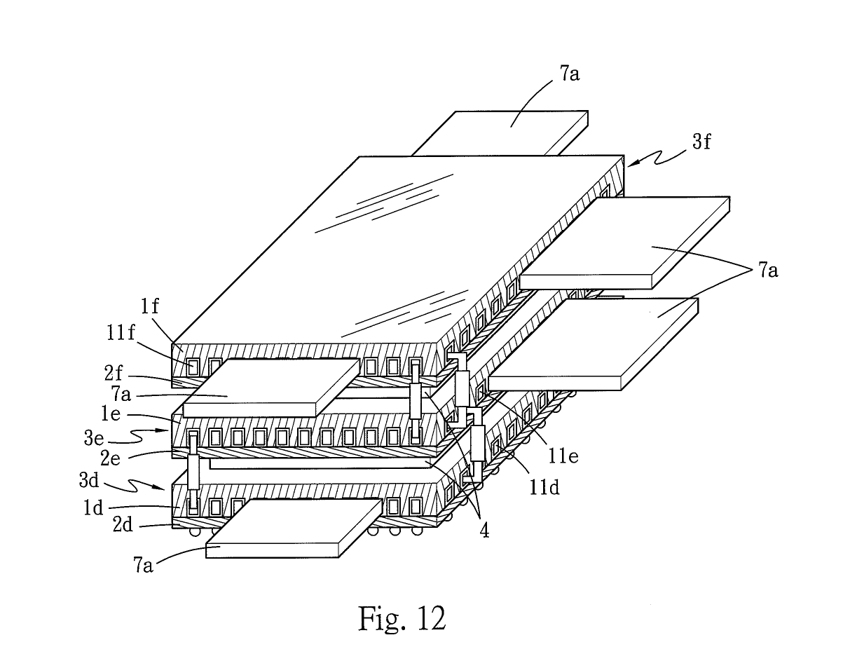

Moreover, the structure made via the embedded package manufacturing method of the invention can be illustrated by referring to FIG. 12. It includes a plurality of packages 3d, 3e and 3f (package 3d is a BGA package, and packages 3e and 3f are LGA packages). The packages 3d, 3e and 3f are coupled with each other through a plurality of intermediate layers 4, and include respectively first circuit substrates 2d, 2e and 2f. The first circuit substrates 2d, 2e and 2f respectively include embedded bodies 1d, 1e and 1f that have respectively a plurality of connection ports 11d, 11e and 11f which are exposed at the outer side of the packages 3d, 3e and 3f. In addition, the embedded package structure of the invention further includes at least one second electronic carrier 7a to form electric connection with the connection port 11d of the package 3d, and the second electronic carrier 7a is the same as the electronic carrier 7 previously discussed, hence can be implemented in an circuit board with the pin, a package element with the pin or a transmission line.

Furthermore, when the embodiments previously discussed are cut at the step 2, the multiple first embedded bodies including the connection ports that are coupled on the same circuit substrate can be arranged and packaged according to a predetermined layout to form a package. While packaging is finished, each package is cut in an array fashion according to a predetermined path to form a plurality of separated package elements to save manufacturing time.

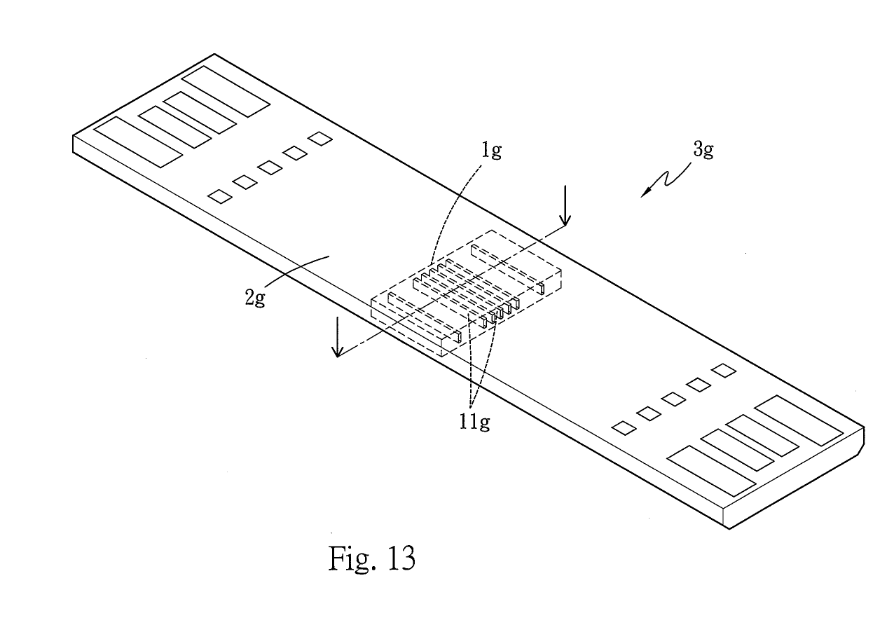

For instance, please referring to FIG. 13, to produce the package 3 depicted in FIG. 1A an first embedded body 1g including connection ports 11g is disposed on a first circuit substrate 2g, then a packaging process is performed to form a package 3g. Next, performing one cutting process with a cutter according to a predetermined path (indicated by arrows in the drawing) to slit the package 3g and embedded body 1g into two separated package elements and also expose the connection ports 11g.

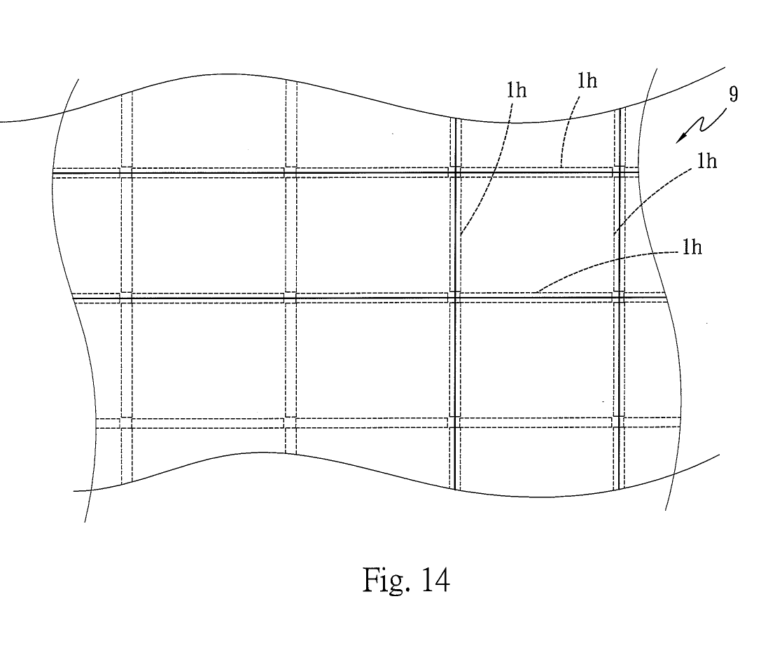

Similarly, as shown in FIG. 14, to produce the MCP or SiP as mentioned in the embodiment 2, a plurality of first embedded bodies 1h including multiple connection ports (not shown in the drawing) can be arranged in a preset layout on a first circuit substrate or a substrate 9 made of a wafer and packaged. Then the substrate 9 is cut according to preset paths corresponding to the arranged layout (indicated by solid lines in the drawing) to form multiple independent package elements and expose the connection ports.

The method of positioning the first embedded bodies and performing cutting after packaging them (not limited to the drawings or description depicted above) as discussed above can further reduce manufacturing time and improve production efficiency.

It is to be noted that the first circuit substrates 2, 2b, 2d, 2e and 2f discussed in the previous embodiments can also be implemented like a package loading board with a separable metal layer disclosed in R.O.C. patent 1421958 (illustrated in FIG. 1I of the said reference); i.e., forming a patterned metal layer which includes a plurality of conductive connection pads on the separable metal layer, and using a packaging material to cover the chip, the conductive connection pads and the separable metal layer, then removing the package loading board to expose the separable metal layer. Thereby the packages 3, 3b, 3d, 3e, 3f and 3g without features of the circuit substrate can be obtained, and they also provide same effect depicted in the invention.

In short, when the invention is implemented according to the manufacturing process of the first embodiment, it is applicable for production of an embedded package structure like a USB flash drive. Details are omitted herein. When the invention is implemented through the manufacturing process of the second embodiment, a stacked structure can be formed by coupling individual packages through intermediate layers, and the corresponding connection ports of the packages can be connected electrically through a connection element to finish the embedded package structure used in SiP.

When the invention is practically adopted on products, the same type of products can be coupled together, such as stacking of flash memories. In addition, products with thousands of high pin count or high complexity or high frequency application (such as products of 3D packaging, MCP, or eMCP) can be used as carriers (such as a wireless communication module), then be coupled in series with other peripheral IC package bodies (such as coupled in series with a GPS module and a multimedia module).

As a conclusion, the invention can be applied on SiP, such as 3D IC, through vertical stacking, horizontal insertion, mixed coupling through stacking and insertion, stacking and insertion after horizontal insertion or the like to get improved applicability. The method of the invention not only can overcome the drawbacks of the conventional techniques that integrate all ICs on the same stack, also can improve yield rate, save time and make assembly and test easier.

While the preferred embodiments of the invention have been set forth for the purpose of disclosure, they are not the limitation of the invention, modifications of the disclosed embodiments of the invention as well as other embodiments thereof may occur to those skilled in the art. Accordingly, the appended claims are intended to cover all embodiments which do not depart from the spirit and scope of the invention.

1. A method for manufacturing an embedded package, comprising the steps of:
Step 1: coupling at least one first embedded body including at least one connection port with a first circuit substrate and packaging the first embedded body and the first circuit substrate to form a package; and
Step 2: exposing the connection port of the package at an outer side of the package.

2. The method of claim 1, wherein the connection port is exposed by cutting the package at step 2.

3. The method of claim 1 further including a step 3 of coupling one side of the package at step 2 with at least one first electronic carrier through at least one intermediate layer.

4. The method of claim 3, wherein the first electronic carrier is electrically connected to the connection port through at least one connecting member.

5. The method of claim 3, wherein the first electronic carrier includes at least one second embedded body and a second circuit substrate that are coupled to each other, the second embedded body including at least one connection port.

6. The method of claim 1, wherein the connection port of the package is inserted by at least one second electronic carrier with a pin thereon.

7. The method of claim 5, wherein the connection port of the first electronic carrier is inserted by at least one second electronic carrier with a pin thereon.

8. The method of claim 6, wherein the second electronic carrier is further inserted by at least one third electronic carrier with a pin thereon.

9. The method of claim 3, wherein the intermediate layer is thermal grease, a silicon substrate, a washer, a metal layer, a dielectric layer or a thin film.

10. The method of claim 4, wherein the connecting member is conductive adhesive, a wire or a plated wire formed via a redistribution layer (RDL) technique.

11. The method of claim 3, wherein the first electronic carrier is a circuit board, a chip, an electronic element or a package element.

12. The method of claim 1, wherein the first embedded body is male or female and formed by an epoxy molding compound (EMC) or injection molding.

13. The method of claim 1, wherein the first embedded body is arranged and packaged according to a predetermined layout to form the package, and the package is further cut according to a predetermined path corresponding to the layout to form a plurality of package elements and expose the connection port.

14. The method of claim 3, wherein the first electronic carrier or the package is treated by sputtering, or the first electronic carrier and the package is interposed by a metal material to prevent electromagnetic interference (EMI).

15. The method of claim 1, wherein the first circuit substrate is a metal carrier board which is selectively removed or patterned.

16. The method of claim 1, wherein the package includes at least one terminal located in the connection port for coupling with the first embedded body and electrically connecting with metal contacts of the first circuit substrate.

17. An embedded package structure comprising at least one package which includes at least one first embedded body, the first embedded body including at least one connection port which is exposed at an outer side of the package.

18. The embedded package structure of claim 17, wherein the package further includes at least one first circuit substrate coupled with the first embedded body.

19. The embedded package structure of claim 17, further including at least one intermediate layer and at least one connecting member, the intermediate layer being located on a surface of the package to couple with a first electronic carrier, the connecting member electrically connecting the package and the first electronic carrier.

20. The embedded package structure of claim 19, wherein the first electronic carrier is a circuit board, a chip, an electronic element or a package element.

21. The embedded package structure of claim 20, wherein the connection port of the package or the first electronic carrier is further inserted by at least one second electronic carrier with a pin thereon to form electric connection, the second electronic carrier being a circuit board, a chip, an electronic element or a package element.

22. The embedded package structure of claim 21, wherein the second electronic carrier is further inserted by at least one third electronic carrier with a pin thereon, the third electronic carrier being a circuit board, a chip, an electronic element or a package element.

23. The embedded package structure of claim 19, wherein the intermediate layer is thermal grease, a silicon substrate, a washer, a metal layer, a dielectric layer or a thin film.

24. The embedded package structure of claim 19, wherein the connecting member is conductive adhesive, a wire or a plated wore formed via a redistribution layer (RDL) technique.

25. The embedded package structure of claim 17, wherein the first embedded body is male or female and formed by an epoxy molding compound (EMC) or injection molding.

26. The embedded package structure of claim 18, wherein the first circuit substrate is a metal carrier board which is selectively removed or patterned.

27. The embedded package structure of claim 18, wherein the package further includes at least one terminal located in the connection port for coupling with the first embedded body and electrically connecting with metal contacts of the first circuit substrate.
